(19) United States
(12) Patent Application Publication
(10) Pub. No.: US 2026/0194744 A1
(43) Pub. Date: Jul. 9, 2026

(54) MEMS MICROMIRROR UNIT AND PRODUCTION THEREOF

(71) Applicant: Carl Zeiss SMT GmbH, Oberkochen (DE)

(72) Inventor: Joachim FRIEDL, Reutlingen (DE)

(21) Appl. No.: 19/555,046

(22) Filed: Mar. 3, 2026

Related U.S. Application Data
(63) Continuation of application No. PCT/EP2024/073169, filed on Aug. 19, 2024.

(30) Foreign Application Priority Data
Sep. 5, 2023 (DE) 10 2023 123 889.2

(51) Int. Cl. G02B 26/08; B81C 3/00; G03F 7/00

(52) U.S. Cl. CPC G02B 26/0833; B81C 3/004; G03F 7/70266; G03F 7/70833; G03F 7/7085

(57) ABSTRACT

A method produces a MEMS micromirror unit for use in apparatuses for semiconductor technology. The MEMS micromirror unit comprises a MEMS mirror array assembly having a MEMS mirror array structure and a joining structure on the side facing away from the MEMS mirror array structure. An interface element secures the MEMS micromirror unit to a superordinate assembly. The superordinate assembly has a joining structure which interlocks with the joining structure of the MEMS mirror array assembly. The superordinate assembly also has at least one abutment surface positioning and/or aligning the MEMS micromirror unit vis-à-vis the superordinate assembly. The disclosure also provides such a MEMS micromirror unit, an apparatus comprising such a MEMS micromirror unit, related methods, and component produced by such methods.

### CROSS-REFERENCE TO RELATED APPLICATIONS

The present application is a continuation of, and claims benefit under 35 USC 120 to, international application No. PCT/EP2024/073169, filed Aug. 19, 2024, which claims benefit under 35 USC 119 of German Application No. 10 2023 123 889.2, filed Sep. 5, 2023. The entire disclosure of each of these applications is incorporated by reference herein.

### FIELD

The disclosure relates to a method for producing a MEMS micromirror unit for use in apparatuses for semiconductor technology and to a MEMS micromirror unit for use in apparatuses for semiconductor technology. The disclosure also relates to an apparatus for semiconductor technology having a corresponding MEMS micromirror unit and to an electronic component produced using such an apparatus.

### BACKGROUND

It is known that apparatuses for semiconductor technology are used for the production or testing of microstructured component parts or the components used for this purpose. One example of such an apparatus is a photolithographic projection exposure apparatus.

Photolithography is used for producing microstructured components, such as e.g. integrated circuits. The projection exposure apparatus used in the process comprises an illumination system and a projection system. The image of a mask (also referred to as a reticle) illuminated by the illumination system is projected so as to reduce the size of the former onto a substrate, for example a silicon wafer, which is coated with a light-sensitive layer and arranged in the image plane of the projection system, using the projection system in order to transfer the mask structure to the light-sensitive coating of the substrate.

In illumination systems, for example for projection exposure apparatuses designed for the EUV range, i.e. for exposure wavelengths from 5 nm to 30 nm, it is generally the case that two facet mirrors are arranged in the beam path between the actual exposure radiation source and the mask to be illuminated, and the mirrors allow homogenization of the radiation in a manner substantially comparable to the principle of a fly's eye condenser. The closer facet mirror in the beam path of the exposure radiation source is often a so-called field facet mirror, and the other facet mirror is a so-called pupil facet mirror.

In order to be able to produce different intensity and/or angle of incidence distributions during the illumination of the mask, it is known for the facets of at least one of the two facet mirrors - for example those of the field facet mirror - to be formed from one or more micromirrors that are electromechanically pivotable on an individual basis. This is disclosed e.g. in WO 2012/130768 A2.

To be able to obtain a small size of the individual micromirrors, it is known for groups of micromirrors to be formed as a so-called MEMS mirror array, i.e. a mirror array made of microelectromechanical systems (MEMS).

Typically, in a MEMS mirror array, a multiplicity of small mirror elements are each mounted so as to be individually movable relative to a common base. For each mirror element, at least one actuator is usually provided and helps enable the mirror element to be adjusted along a respectively predefined degree of freedom. The mirror elements are frequently pivotable about two axes extending perpendicular to one another and parallel to the base, in which case enough actuators can then also be provided to help allow the mirror element to pivot about precisely these axes independently of one another. For the individual mirror elements, sensors can also be provided and enable the position of the mirror element to be determined relative to the base, so that the alignment of the mirrors can be monitored. An embodiment for the mirrors of a MEMS mirror array is described in DE 10 2015 204 874 A1.

A method for producing a micromirror or a MEMS mirror array comprising a plurality of such micromirrors is disclosed—together with further details relating to a possible configuration of the micromirror—in DE 10 2015 220 018 A1.

In order to form a facet mirror for a projection exposure apparatus, a plurality of MEMS mirror arrays can be secured to a superordinate assembly in a densely populated, planar grid arrangement. For this purpose, the MEMS mirror arrays can be designed as MEMS micromirror units (“micromirror units”, MMU), which in addition to the actual MEMS mirror arrays can also have an interface element as well, by which the units can be secured to the superordinate assembly.

### SUMMARY

Often, for MEMS mirrors array to be arranged a small distance from one another for the stated purpose of use and to have the desired precise position and alignment in the inserted and secured state in the assembly, the individual mirror elements of a MEMS micromirror unit are positioned and aligned with relatively high precision relative to its interface element.

The disclosure seeks to provide an improved method for producing a MEMS micromirror unit and a MEMS micromirror unit.

In an aspect, the disclosure provides a method for producing a MEMS micromirror unit for use in apparatuses for semiconductor technology comprising a MEMS mirror array assembly having a MEMS mirror array structure and a joining structure arranged on the side facing away from the MEMS mirror array structure and an interface element for securing the MEMS micromirror unit to a superordinate assembly having a joining structure which interacts in interlocking fashion with the joining structure of the MEMS mirror array assembly and at least one abutment surface for positioning and/or aligning the MEMS micromirror unit vis-à-vis the superordinate assembly, including the steps of:
measuring the relative position and pose of the MEMS mirror array structure with respect to the joining structure of the MEMS mirror array assembly; and
adapting the relative position and/or pose of the joining structure of the interface element and of the at least one abutment surface, in such a way that the relative position and/or pose of the MEMS mirror array structure and the at least one abutment surface corresponds to a predetermined position and pose once the MEMS mirror array assembly and interface element have been joined by way of the joining structures.

In an aspect, the disclosure provides a MEMS micromirror unit for use in apparatuses for semiconductor technology comprising a MEMS mirror array assembly having a MEMS mirror array structure and a joining structure arranged on the side facing away from the MEMS mirror array structure and an interface element for securing the MEMS micromirror unit to a superordinate assembly having a joining structure which interacts in interlocking fashion with the joining structure of the MEMS mirror array assembly and at least one abutment surface for positioning and/or aligning the MEMS micromirror unit vis-à-vis the superordinate assembly, wherein the MEMS micromirror unit is produced according to the disclosure.

In an aspect, the disclosure provides an apparatus for semiconductor technology, comprising at least one MEMS micromirror unit according to the disclosure, which is used to deflect radiation used by the apparatus, for example for exposing an object. In an aspect, the disclosure provides an electronic component produced using an appropriate semiconductor technology apparatus, with the component optionally comprising structures in the micrometer and/or nanometer range.

In the context of the present disclosure, “apparatus for semiconductor technology” denotes any apparatus that can be used for the production or testing of microstructured component parts or the components used for this purpose. Besides photolithographic projection exposure apparatuses, this can also encompass inspection apparatuses and metrology systems. In the case of inspection apparatuses for masks or wafers, e.g. the variability of the illumination can be increased with the aid of one or more MEMS micromirror units, which can result in higher-contrast or totally new image representations of the surface of a mask or wafer, which can be desirable for the inspection of mask or wafer. This comparably also applies to metrology systems that can be used to measure masks, wafers or any other optical elements, such as mirrors, for example, in which case an increased variability in the illumination can improve the measurement results.

The disclosure provides the insight that solely reducing the permissible tolerances when producing the individual components of a MEMS micromirror unit and joining the components may not allow, or at least may not readily allow, attainment of the accuracy —desired for the use of such a MEMS micromirror unit in an apparatus for semiconductor technology—of the position and pose of the individual mirror elements vis-à-vis the abutment surfaces of the interface element used to define the position and alignment vis-à-vis the superordinate assembly of the MEMS micromirror unit overall. In embodiments, the disclosure provides for the actual MEMS mirror array structure and possible further elements to be combined to form a MEMS mirror array assembly which comprises a defined joining structure on the side facing away from the MEMS mirror array structure. If a corresponding assembly is available, the position and pose of the MEMS mirror array structure can be measured precisely vis-à-vis the joining structure. Using the position and pose information resulting from this measurement as a basis, it is possible to subsequently adapt the interface element in such a way that following the joining of MEMS mirror array assembly and interface element at the joining structures provided for this purpose, the interlocking interaction thereof, which is consequently accurate in position and pose, yields—with sufficiently high precision—a predetermined position and pose of the MEMS mirror array structure vis-à-vis those abutment surface(s) on the interface element used to at least partially fix the position and pose of the MEMS micromirror unit vis-à-vis a superordinate assembly.

The relevant adaptation of the relative position and/or pose of the joining structure of the interface element and of the at least one abutment surface can be effected by adapting the joining structure of the interface element. To this end, the surfaces of the interface element provided for the form fit can be suitably modified, for example by machining. For example, for this purpose, the interface element in the initial state can be a blank in which the surfaces in question are not yet designed or only designed so rudimentarily that the surfaces ultimately desired for the form fit can be produced purely by machining, for example using a CNC milling machine.

In an alternative to that or in addition, the relative position and/or pose of the joining structure of the interface element and of the at least one abutment surface can also be adapted by virtue of at least one of the at least one abutment surfaces being adapted, e.g. by machining. This, too, allows the position and pose of the abutment surfaces to be defined vis-à-vis the joining structure of the interface element and—after the MEMS mirror array assembly was joined—also vis-à-vis the MEMS mirror array structure. To help allow an adaptation by machining, the basic regions of an interface element blank which can be provided as abutment surfaces to have sufficient material excess.

The interface element can be formed in two parts. In this context, the main element of the interface element forms the joining structure for connection to the MEMS mirror array assembly. A compensating element which in turn forms the at least one abutment surface of the interface element can be secured to this main element in a predetermined pose and position—predetermined at least in part by e.g. suitable shaping. An adaptation of the relative position and/or pose of the joining structure of the interface element and of the at least one abutment surface can be achieved solely by processing the compensating element.

If the compensating element has a geometrically simple shape, then it may be easy to perform the processing of the compensating element desired for the adaptation. For example, the compensating element could be a compensating sleeve, the inner or outer contour of which—for connection to the main element or for contact with a superordinate assembly—is fixedly predetermined, while the respective other contour can be modified. It goes without saying that the same also applies to the end faces of the compensating sleeve, which may likewise represent abutment surfaces. The combination of main element and compensating element in the predetermined position and/or pose relative to each other then forms an interface element as provided according to the disclosure. In this case, it may be irrelevant whether the main element and the compensating element are initially joined together or whether the main element is joined to the MEMS mirror array assembly in a first step and the compensating element is only subsequently attached.

In view of the two-part embodiment of the interface element explained above, it should also be noted that when an element comparable to the main element is connected to the MEMS mirror array assembly or formed in one piece therewith, the area provided for connection to an element comparable to the compensating element can be subsequently measured and the element comparable to the compensating element can be adapted on the basis of this measurement before it is attached, the element comparable to the main element should be regarded as a part of the MEMS mirror array assembly, and the element comparable to the compensating element is the actual interface element.

The relative position and/or pose of the joining structure of the interface element and of the at least one abutment surface can be adapted in at least two, such as three, translational degrees of freedom and/or at least one, for example two rotational degrees of freedom. In this way, the position can be adapted in the direction of the base area of the MEMS mirror array structure and/or perpendicularly thereto. In an alternative to that or in addition, the inclination of the MEMS mirror array structure vis-à-vis the interface element can also be modified. In other words, the relative pose should be influenced by a rotation about two axes running parallel to the base area of the MEMS mirror array structure.

The number and configuration of the abutment surfaces on the interface element can be chosen such that, when inserted into the superordinate assembly, as few degrees of freedom as reasonably possible remain, such as one degree of freedom (for example one translational degree of freedom for the insertion or subsequent removal of the MEMS micromirror unit) or two degrees of freedom (additionally e.g. a rotational degree of freedom about the first translational degree of freedom). Degrees of freedom possibly remaining directly after the insertion can then be blocked by a suitable fixing mechanism. An appropriate fixation can be obtained, for example, via a force fit and/or form fit, e.g. by screwing.

The joining structures of the MEMS mirror array assembly and interface element can be configured to self-center. As result, when the MEMS mirror array assembly and interface element are joined, it is possible to ensure that the relative position and/or pose affected by the self-centration can be reached with a high accuracy, and this is also beneficial to the accuracy of the relative pose of the MEMS mirror array structure and the at least one abutment surface. The joining structures can further comprise a travel stop for the degree of freedom in the direction of the self-centering axis. A relatively high positional accuracy is also achievable in this direction in that case.

For example, the joining structure of the MEMS mirror array assembly may comprise a cylindrically shaped projection. In that case, the joining structure of the interface element may comprise a corresponding cylindrical receptacle which—as explained above—may be adapted when desired. In addition, the base area at the free end of the projection and/or the surface from which the projection protrudes may be in the form of a travel stop. The extent to which the two joining structures engage during joining can then be predetermined by way of the travel stop.

Actual joining of the MEMS mirror array assembly and interface element can be brought about by force fit or integral bond.

Shrink-fitting, for example, can be used as the joining process if the joining structures are of suitable form. Here, the two joining structures can be manufactured relative to one another for an interference fit, and one joining structure can be heated for joining, such that the interference fit temporarily changes to a transition fit or clearance fit in which the parts to be joined can be slid into one another. This can return to an interference fit after cooling, meaning a force-fitting connection. Inserts made of indium can be provided between the surfaces provided for forming the force fit if the force-fit connection should have a gas-tight configuration.

If the intention is to create a cohesive connection, the MEMS mirror array assembly and the interface element can be joined by soldering. Should the contact region between the MEMS mirror array assembly and the interface element not offer any surface on the MEMS mirror array assembly and/or interface element made of a material suitable for soldering, then the MEMS mirror array assembly and/or the interface element can be provided in the relevant regions with a coating suitable for soldering, for example a metallic coating.

In addition to the MEMS mirror array structure and the joining structure, the MEMS mirror array assembly may comprise at least one substrate having at least one application-specific integrated circuit, a rewiring element for converting the MEMS mirror array structure contacts into those contacts, generally larger contacts, to which control and supply cables can be plugged or soldered, and/or a spacer element, for example for forming a cavity for receiving electronic elements for example. The specified elements—generally like the MEMS mirror array structure as well—may be manufactured on a silicon-based basis. The connections between the elements can be highly thermally conductive such that there can be dissipation from the MEMS mirror array structure via the MEMS mirror array assembly by thermal conduction. The defined joining structure can be formed in one piece with the element of the MEMS mirror array assembly farthest away from the MEMS mirror array structure. In this way, a separate joining structure element can be dispensed with.

Generally, each element of the MEMS mirror array assembly and the connections between two adjacent elements are subject to tolerances which, in total, exceed the desired tolerances for apparatuses for semiconductor technology but can be adequately compensated for by the method according to the disclosure.

The interface element can have a cylindrical or frustoconical basic shape, wherein at least one abutment surface can be formed at least in part by the basic shape. A corresponding configuration of the interface element has proven beneficial.

For an explanation of the MEMS micromirror unit according to the disclosure, reference is made to the statements above.

An example of a MEMS micromirror produced in accordance with a method according to the disclosure can be provided on the basis of comparative examinations of at least two MEMS micromirror units. If two examined MEMS micromirror units of identical construction both have, in principle, identical—i.e. within tolerances which are considered to be permissible—relative positions and poses of the MEMS mirror array structure and the at least one abutment surface but a contact surface, which influences this position and pose, between two components of the MEMS micromirror units exhibits differences which go beyond the customary tolerance, then the assumption can be made that the contact surface in question was adapted in accordance with the method according to the disclosure.

For an explanation of the semiconductor technology apparatus according to the disclosure, reference is made to the above statements. For example, the apparatus can be a photolithographic projection exposure apparatus. In this context, the at least one MEMS micromirror unit can be arranged in the illumination system.

### BRIEF DESCRIPTION OF THE DRAWINGS

The disclosure is described by way of example on the basis of certain embodiments with reference to the accompanying drawings, in which:

FIG. 1: shows a schematic illustration of a photolithographic projection exposure apparatus comprising MEMS micromirror units;

FIGS. 2A-2C: show schematic illustrations of a production method;

FIG. 3: shows a schematic illustration of an interface element;

FIGS. 4A-4C: show schematic illustrations of a production method; and

FIG. 5: shows a schematic illustration of a starting point for a production method.

### DETAILED DESCRIPTION

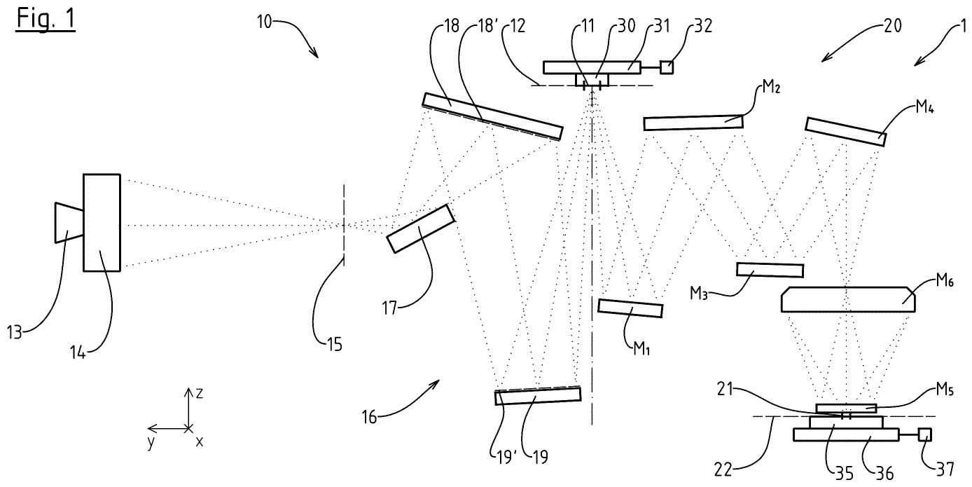

FIG. 1 illustrates a schematic meridional section through a photolithographic projection exposure apparatus 1 as an example of an apparatus for semiconductor technology. In this case, the projection exposure apparatus 1 comprises an illumination system 10 and a projection system 20.

An object field 11 in an object plane or reticle plane 12 is illuminated with the aid of the illumination system 10. For this purpose, the illumination system 10 comprises an exposure radiation source 13, which, in the illustrated exemplary embodiment, emits illumination radiation at least comprising used light in the EUV range, i.e. with a wavelength of between 5 nm and 30 nm for example. The exposure radiation source 13 can be a plasma source, for example an LPP (laser produced plasma) source or a GDPP (gas discharge produced plasma) source. It can also be a synchrotron-based radiation source. The exposure radiation source 13 can also be a free electron laser (FEL).

The illumination radiation emerging from the exposure radiation source 13 is initially focused in a collector 14. The collector 14 can be a collector with one or more ellipsoidal and/or hyperboloidal reflection surfaces. The illumination radiation can be incident on the at least one reflection surface of the collector 14 with grazing incidence (GI), i.e. at angles of incidence of greater than 45°, or with normal incidence (NI), i.e. at angles of incidence of less than 45°. The collector 14 can be structured and/or coated on the one hand for optimizing its reflectivity for the used radiation and on the other hand for suppressing extraneous light.

Downstream of the collector 14, the illumination radiation propagates through an intermediate focus in an intermediate focal plane 15. If the illumination system 10 is constructed in a modular design, the intermediate focal plane 15 can be used, in general, for the separation—including the structural separation—of the illumination system 10 into a radiation source module, comprising the exposure radiation source 13 and the collector 14, and the illumination optics unit 16 described below. In the case of a corresponding separation, radiation source module and illumination optics unit 16 then jointly form a modularly constructed illumination system 10.

The illumination optics unit 16 comprises a deflection mirror 17. The deflection mirror 17 can be a plane deflection mirror or alternatively a mirror with a beam-influencing effect going beyond the pure deflection effect. In an alternative to that or in addition, the deflection mirror 17 can be embodied as a spectral filter that separates a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged in a plane of the illumination optics unit 16 which is optically conjugate to the reticle plane 12 as a field plane, then this facet mirror is also referred to as a field facet mirror.

The first facet mirror 18 comprises a multiplicity of micromirrors 18′ that are individually pivotable about two mutually perpendicular axes in each case, for the purpose of controllably forming facets which can each be configured with an orientation sensor (not illustrated) for determining the orientation of the micromirror 18′. The first facet mirror 18 is thus a microelectromechanical system (MEMS system), as also described in DE 10 2008 009 600 A1, for example.

A second facet mirror 19 is arranged downstream of the first facet mirror 18 in the beam path of the illumination optics unit 16, with the result that this yields a doubly faceted system, the fundamental principle of which is also referred to as a fly's eye integrator. If the second facet mirror 19—as in the illustrated exemplary embodiment—is arranged in a pupil plane of the illumination optics unit 16, it is also referred to as a pupil facet mirror. However, the second facet mirror 19 can also be arranged at a distance from a pupil plane of the illumination optics unit 16, as a result of which a specular reflector arises from the combination of the first and the second facet mirror 18, 19, for example as described in US 2006/0132747 A1, EP 1 614 008 B1 and U.S. Pat. No. 6,573,978.

The second facet mirror 19 need not be constructed from pivotable micromirrors but rather can comprise individual facets formed from one mirror or a manageable number of mirrors which are significantly larger than micromirrors, which facets are either stationary or tiltable only between two defined end positions. It is however—as illustrated—also possible, in the second facet mirror 19, to provide a microelectromechanical system having a multiplicity of micromirrors 19′ that are individually pivotable about two mutually perpendicular axes in each case, each optionally comprising an orientation sensor.

The individual facets of the first facet mirror 18 are imaged into the object field 11 with the aid of the second facet mirror 19, with this regularly only being approximate imaging. The second facet mirror 19 can be the last beam-shaping mirror or else actually the last mirror for the illumination radiation in the beam path upstream of the object field 11.

In each case one of the facets of the second facet mirror 19 is assigned to exactly one of the facets of the first facet mirror 18 for the purpose of forming an illumination channel for illuminating the object field 11. This can result in illumination according to the Köhler principle.

The facets of the first facet mirror 18 are imaged overlaid on one another by way of a respective assigned facet of the second facet mirror 19, for the purpose of illuminating the object field 11. Here, the illumination of the object field 11 is as homogeneous as possible. It can have a uniformity error of less than 2%. Field uniformity can be achieved by overlaying different illumination channels.

By selecting the used illumination channels, which can be possible by way of a suitable setting of the micromirrors 18′ of the first facet mirror 18, it is still possible to set the intensity distribution in the entrance pupil of the projection system 20 described below. This intensity distribution is also referred to as illumination setting. Incidentally, it may be desirable here to arrange the second facet mirror 19 not exactly in a plane that is optically conjugate to a pupil plane of the projection system 20. For example, the pupil facet mirror 19 can be arranged tilted relative to a pupil plane of the projection system 20, as is described in DE 10 2017 220 586 A1, for example.

In the arrangement of the components of the illumination optics unit 16 as illustrated in FIG. 1, however, the second facet mirror 19 is arranged in an area conjugate to the entrance pupil of the projection system 20. Deflection mirror 17 and the two facet mirrors 18, 19 are arranged tilted both vis-à-vis the object plane 12 and vis-à-vis one another in each case.

In an alternative embodiment (not illustrated) of the illumination optics unit 16, a transfer optics unit comprising one or more mirrors can additionally be provided in the beam path between the second facet mirror 19 and the object field 11. The transfer optics unit can comprise one or two normal-incidence mirrors (NI mirrors) and/or one or two grazing-incidence mirrors (GI mirrors). Using an additional transfer optics unit, it is possible to take account of different poses of the entrance pupil for the tangential and for the sagittal beam path of the projection system 20 described below.

It is possible for the deflection mirror 17 illustrated in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 with the aid of the projection system 20.

For this purpose, the projection system 20 comprises a plurality of mirrors Mᵢ, which are consecutively numbered in accordance with their arrangement in the beam path of the projection exposure apparatus 1.

In the example illustrated in FIG. 1, the projection system 20 comprises six mirrors M₁ to M₆. Alternatives with four, eight, ten, twelve or any other number of mirrors Mᵢ are likewise possible. The penultimate mirror M₅ and the last mirror M₆ each have a passage opening for the illumination radiation, as a result of which the illustrated projection system 20 is a doubly obscured optics unit. The projection system 20 has an image-side numerical aperture that is greater than 0.3 and can also be greater than 0.6 and can be for example 0.7 or 0.75.

The reflection surfaces of the mirrors Mᵢ can be in the form of freeform surfaces without an axis of rotational symmetry. However, the reflection surfaces of the mirrors Mᵢ can alternatively also be designed as aspherical surfaces with exactly one axis of rotational symmetry of the reflection surface shape. Just like the mirrors of the illumination optics unit 16, the mirrors Mᵢ can have highly reflective coatings for the illumination radiation. These reflective coatings can be designed as multilayer coatings, for example with alternating layers of molybdenum and silicon.

The projection system 20 has a large object-image shift in the y-direction between a y-coordinate of a center of the object field 11 and a y-coordinate of the center of the image field 21. This object-image shift in the y-direction can be of approximately the same magnitude as a z-distance between the object plane 12 and the image plane 22.

For example, the projection system 20 can be designed to be anamorphic, i.e. it has different imaging scales βₓ, β_{y} in the x- and y-directions for example. The two imaging scales βₓ, β_{y} of the projection system 20 can be (βₓ, β_{y})=(+/−0.25, /+−0.125). An imaging scale β of 0.25 corresponds here to a reduction with a ratio of 4:1, while an imaging scale β of 0.125 results in a reduction with a ratio of 8:1. A positive sign in the case of the imaging scale β means imaging without image inversion; a negative sign means imaging with image inversion.

Other imaging scales are likewise possible. Imaging scales βₓ, β_{y} with the same sign and the same absolute magnitude in the x-and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

For example, the projection system 20 can comprise a homocentric entrance pupil. The latter can be accessible. However, it can also be inaccessible.

A reticle 30 (also referred to as mask) arranged in the object field 11 is exposed by the illumination system 10 and transferred by the projection system 20 onto the image plane 21. The reticle 30 is held by a reticle holder 31. The reticle holder 31 is displaceable for example in a scanning direction by way of a reticle displacement drive 32. In the exemplary embodiment illustrated, the scanning direction runs in the y-direction.

A structure on the reticle 30 is imaged onto a light-sensitive layer of a wafer 35 arranged in the region of the image field 21 in the image plane 22. The wafer 35 is held by a wafer holder 36. The wafer holder 36 is displaceable, for example in the y-direction, using a wafer displacement drive 37. The displacement, firstly, of the reticle 30 by way of the reticle displacement drive 32 and, secondly, of the wafer 35 by way of the wafer displacement drive 37 can be synchronized with one another.

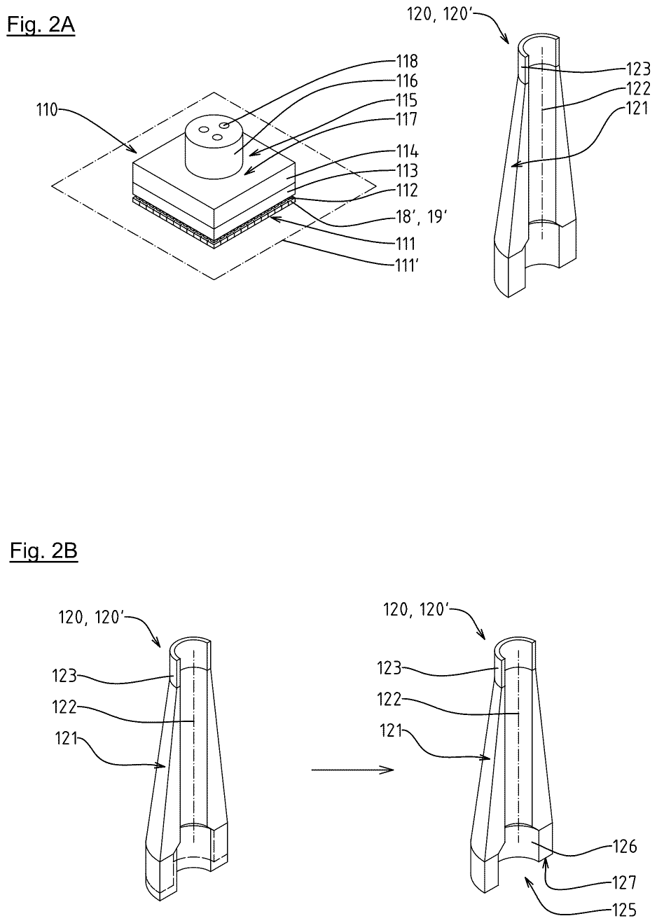

The projection exposure apparatus 1 illustrated in FIG. 1, or its illumination system 10, the above description of which refers to certain known technology, can be distinguished by each of the first and/or second facet mirror 18, 19 comprising a plurality of MEMS micromirror units 100 according to the disclosure (cf. FIGS. 2A-2C, 3 and 4A-4C), with the MEMS micromirror units 100 each comprising a plurality of micromirrors 18′, 19′. The individual MEMS micromirror units 100 can be secured on a superordinate assembly in order to jointly form the facet mirrors 18, 19 schematically depicted in FIG. 1. In addition to mechanical securing, the superordinate assembly can also provide one or more desired links of the individual MEMS micromirror units 100, for example to control electronics and/or cooling circuits.

FIGS. 2A-2C schematically illustrate a first exemplary embodiment of a MEMS micromirror unit 100 according to the disclosure, as may be used in FIG. 1, and for example the method according to the disclosure for the production thereof.

The structure of the MEMS micromirror unit 100 is initially explained on the basis of FIG. 2C.

The MEMS micromirror unit 100 comprises a MEMS mirror array assembly 110 and an interface element 120 fixedly connected thereto.

The actual MEMS mirror array structure 111 comprising a multiplicity of micromirrors 18′, 19′ is a part of the MEMS mirror array assembly 110. In the exemplary embodiment illustrated, 12×12=144 micromirrors 18′, 19′ are arranged in a grid-like manner in a common plane 111′. In this case, the MEMS mirror array structure 111 also comprises all actuators and sensors for the individual pivoting of each of the micromirrors 18′, 19′, as already described above.

The MEMS mirror array structure 111 is arranged on a rewiring element 113 made of a multilayer ceramic with metallic rewiring planes between the individual ceramic layers, e.g. a high-temperature multilayer ceramic (“high-temperature cofired ceramic”, HTCC), wherein a substrate 112, likewise based on silicon, with application-specific integrated circuits is also provided between the rewiring element 113 and the MEMS mirror array structure 111. With the rewiring substrate 113, the electrical contacts of the MEMS mirror array structure 111 and of the application-specific integrated circuits that are provided for operation are converted into electrical contacts to which e.g. electrical control and supply lines can be connected. Additionally, the rewiring substrate 113 imparts a structural integrity to the MEMS mirror array structure 111 and the substrate 112 with the application-specific integrated circuits which the MEMS mirror array structure 111 and the substrate 112 on their own might not have to a sufficient extent.

A spacer element 114 is fixedly connected to the rewiring element 113 and forms an internal cavity (not illustrated) together with the rewiring element 113, wherein e.g. further integrated circuits or else connectors of control and supply lines for the MEMS mirror array structure 111 can be arranged in the cavity. Additionally, cooling lines may be guided in the cavity in order to dissipate heat, especially from the MEMS mirror array structure 111. To this end, the MEMS mirror array structure 111, the substrate 112 with the application-specific integrated circuits, the rewiring element 113 and the spacer element 114 should be configured in heat-conducting fashion and should be connected such that heat arising at the MEMS mirror array structure 111 can be conducted to the cavity and, from there, into optionally present cooling lines.

A joining structure 115 is formed in one piece with the spacer element 114 as the element of the MEMS mirror array assembly 110 farthest away from the MEMS mirror array structure 111. In this case, the joining structure 115 is in the form of a cylindrically shaped projection 116, wherein the surface 117 of the spacer element 114 from which the projection 116 protrudes serves as a travel stop. Feedthroughs 118 through which supply and control lines can be guided into the cavity formed by the spacer element 114 and the rewiring element 113 are provided in the cylindrical projection 116.

The interface element 120 is secured to the joining structure 115 of the MEMS mirror array assembly 110. The rotationally symmetric interface element 120 is illustrated only in section in all the figures as a matter of principle, in order to illustrate the interior thereof and the interaction with the MEMS mirror array assembly 110.

The interface element 120 made of metal has a substantially frustoconical basic shape. In this case, the lateral face of the conical frustum region of the interface element 120 serves as an abutment surface 121, with which the MEMS micromirror unit 100 can be inserted into a conical receptacle of a superordinate assembly in interlocking fashion. Following the insertion into such a conical receptacle, one degree of freedom, specifically a rotational degree of freedom about the longitudinal axis 122 of the interface element 120, remains for the MEMS micromirror unit 100. In order to secure the MEMS micromirror unit 100 in a conical receptacle, the free end of the interface element 120 is provided with a threaded region 123 which can be used to brace the interface element 120 in the receptacle in such a way that there is force fit at the abutment surface 121 which can also suppress the two mentioned degrees of freedom.

At the opposite end to the threaded region 123, the interface element 120 comprises a joining structure 125 which corresponds to the joining structure 115 on the MEMS mirror array assembly 110: The joining structure 125 comprises a cylindrical receptacle 126 which is adapted to the cylindrical projection 116 with an oversize and comprises a travel stop 127 which rests against the travel stop 117 in the assembled state of the MEMS micromirror unit 110. To connect interface element 120 and MEMS mirror array assembly 110, the former is heated in order to be subsequently shrunk onto the cylindrical projection 116 of the MEMS mirror array assembly 110. In this case, the joining structures 117, 127 are self-centering, specifically about the axis of the cylindrical projection 116. If the two travel stops 117, 127 are in contact in the process, then the degree of freedom in the direction of the axis of the cylindrical projection 116 is also limited and only the angular position of the interface element 120 vis-à-vis the MEMS mirror array assembly 110 about the longitudinal axis 122 of the interface element 120 remains undetermined. However, this angular position can also be specified and precisely maintained by way of suitable markings on interface element 120 and MEMS mirror array assembly 110.

The interface element 120 is of hollow design such that supply and control lines can be passed through.

So that the MEMS micromirror unit 100 can be used in a photolithographic projection exposure apparatus, especially in EUV projection exposure apparatuses, as a part of a facet mirror 18, 19, the pose and position of the individual micromirrors 18′, 19′ vis-à-vis the abutment surface 121 on the interface element meets the corresponding specifications within a narrow range of tolerance. Thus, the position of the micromirrors 18′, 19′ in the plane 111′ may deviate by e.g. a maximum of 10 μm from a position specification vis-à-vis the abutment surface 121 in the case of some projection exposure apparatuses. Here, the angle of inclination of the plane 111′ vis-à-vis the abutment surface 121 should deviate by e.g. a maximum of 0.2° from the target.

In order to achieve these specifications in the case of the MEMS micromirror unit 100 depicted in FIG. 2C, the unit has been produced using a method according to the disclosure, as sketched out in FIGS. 2A-2C.

In the initial state for the method according to the disclosure depicted in FIG. 2A, the MEMS mirror array assembly 110 is already completely present, i.e. the individual elements 111-114 have already been completely joined together. The interface element 120 is in the form of a blank 120′, in which, inter alia, the abutment surface 121 has already been produced in full, but the joining region 125 still has a certain amount of excess material.

In the first step of the method (FIG. 2A), the position and pose of the MEMS mirror array structure 111 is measured with high precision vis-à-vis the joining structure 115 of the MEMS mirror array assembly 110. For the pose and position established thus, all deviations from the ideal assembly that arise during the production and joining of the individual elements 111-114 of the MEMS mirror array assembly 110 are taken into account.

Subsequently, the measurement of the MEMS mirror array assembly 110 is used to establish how the joining structure 125 on the interface element 120 should be designed so that, as a result, the desired pose and position of the MEMS mirror array structure 111 is precisely obtained vis-à-vis the abutment surface 121 as soon as MEMS mirror array assembly 110 and interface element 120 are joined together properly.

In FIG. 2B the correspondingly established design for the joining structure 125 of the interface element 120 on the blank 120′ is drawn in dashed lines on the left-hand side. On the basis of design established thus, the blank 120′ can be machined—e.g. using a CNC milling machine—such that, as a result, an interface element 120 with the desired design is available.

The interface element 120 prepared in this way can subsequently be joined to the MEMS mirror array assembly 110, as already described, such that a MEMS micromirror unit 100 is available, in which specifications relating to pose and position of the MEMS mirror array structure 111 vis-à-vis the abutment surface 121 are met with the desired accuracy.

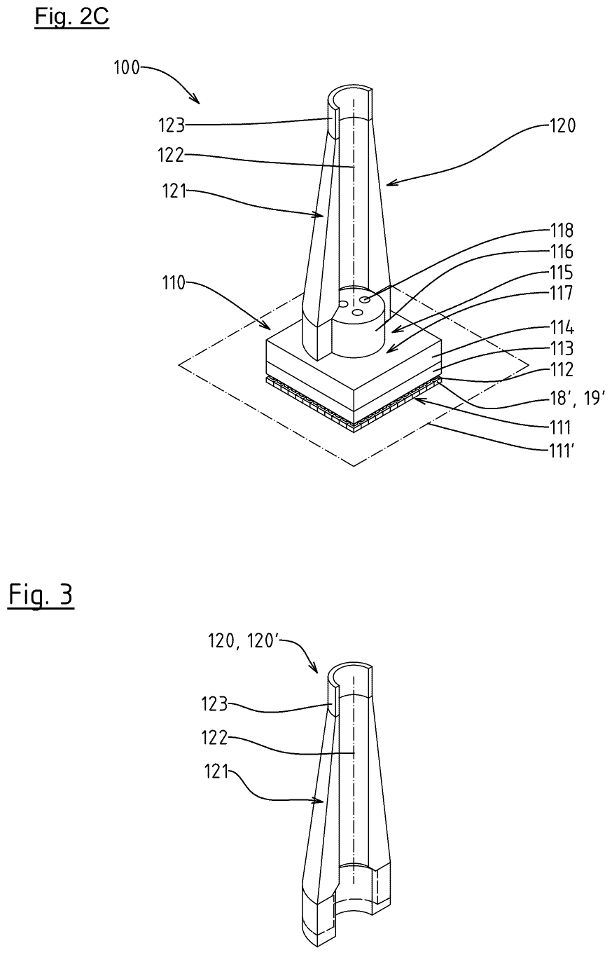

Purely for illustrative purposes, practically no position and pose deviations are to be compensated for in the exemplary embodiment illustrated in FIGS. 2A-2C, which is why the established and ultimately implemented design of the joining structures 125 of the interface element 120 appears symmetric. In order to clarify that larger position and pose deviations can also be compensated for in the exemplary embodiment according to FIGS. 2A-2C, FIG. 3 depicts, using dashed lines and for a MEMS mirror array assembly 110 (not illustrated here), an established design for the joining structure 125 which is used to compensate for not only a not inconsiderable positional deviation between MEMS mirror array structure 111 and the joining structure 115 of the MEMS mirror array assembly 110 (not illustrated here) in three degrees of freedom (specifically in the plane 111′ (cf. FIG. 2A) and perpendicular thereto) but also a pose deviation about two rotational degrees of freedom (specifically about two axes of rotation lying in the plane 111′ (cf. FIG. 2A).

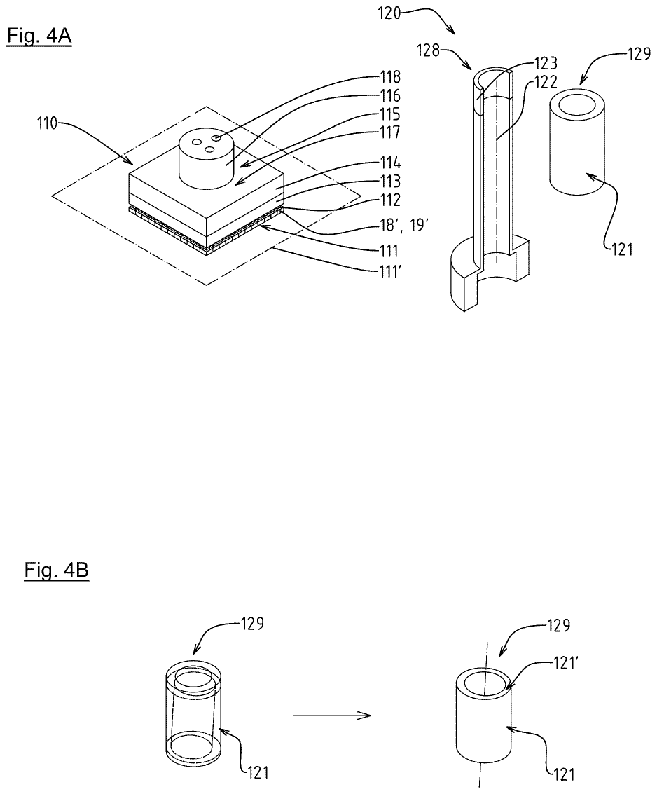

FIGS. 4A-4C illustrate a second exemplary embodiment of a method according to the disclosure and a second exemplary embodiment of a MEMS micromirror unit 100 according to the disclosure. The exemplary embodiment is similar to that from FIGS. 2A-2C, which is why reference is made to the explanations given there, and only the differences between the two exemplary embodiments will be discussed below.

The interface element 120 is embodied in two parts in the exemplary embodiment according to FIGS. 4A-4C. Thus, the interface element 120 comprises a main element 128 (which is only illustrated in section as a matter of principle) and a compensating element 129 separate therefrom in the initial state (cf. FIG. 4A).

The main element 128 has a cylindrical basic shape, at the end of which provision is made for a joining structure 125 which is already completely adapted to the joining structure 116 of the MEMS mirror array assembly 110 in the initial state (FIG. 4A), i.e. which can be connected thereto in a force-fitting manner solely by shrink fitting. Once again, a threaded region 123 allowing fixation to a superordinate assembly is provided at the other end.

The compensating element 129 is designed as a compensating sleeve, the outer jacket of which is provided as the subsequent abutment surface 121 and the inner radius of which, however, is smaller than the decisive outer radius of the main element 128.

After the measurement of the MEMS mirror array assembly 110 in a manner analogous to FIG. 2A, a target design for the compensating element 129 is subsequently established which, following the correct assembly of the main element 128 and compensating element 129 to form the interface element 120 and following the joining of the interface element 120 with the MEMS mirror array assembly 110, gives rise to the MEMS micromirror unit 100 depicted in FIG. 4C, in which two abutment surfaces 121, 121′ are present and can interact with a suitable receptacle of a superordinate assembly in such a way as to ensure a predetermined pose and position of the MEMS mirror array structure 111 vis-à-vis the superordinate assembly.

FIG. 4B, left-hand side, shows the compensating element 129 as a blank 129′, wherein the established target design is already depicted using dashed lines. It is evident that only the inner contour and the end faces of the compensating element 129 are to be processed here in order to achieve the target design. For example, the outer jacket provided as abutment surface 121 need not be processed and can e.g. be used to clamp the blank 129 in a CNC milling machine and/or an adjusting lathe. The fully processed compensating element 129 is depicted on the right-hand side of FIG. 4B.

To complete the MEMS micromirror unit 100 as depicted in FIG. 4A, the compensating element 129 is initially secured to the main element 128 by an integral bond, specifically by soldering or thermal joining, in order to create a shrink fit of the two elements 128, 129 made of metal. Maintaining the correct angular position of the compensating element 129 vis-à-vis the main element 128 can be ensured by suitable markings on the two elements 128, 129. Subsequently, the interface element 120 assembled in this way is fixedly connected to the MEMS mirror array assembly 111 by shrinking it onto the joining structure 115, wherein the correct angular position can be ensured again by suitable markings.

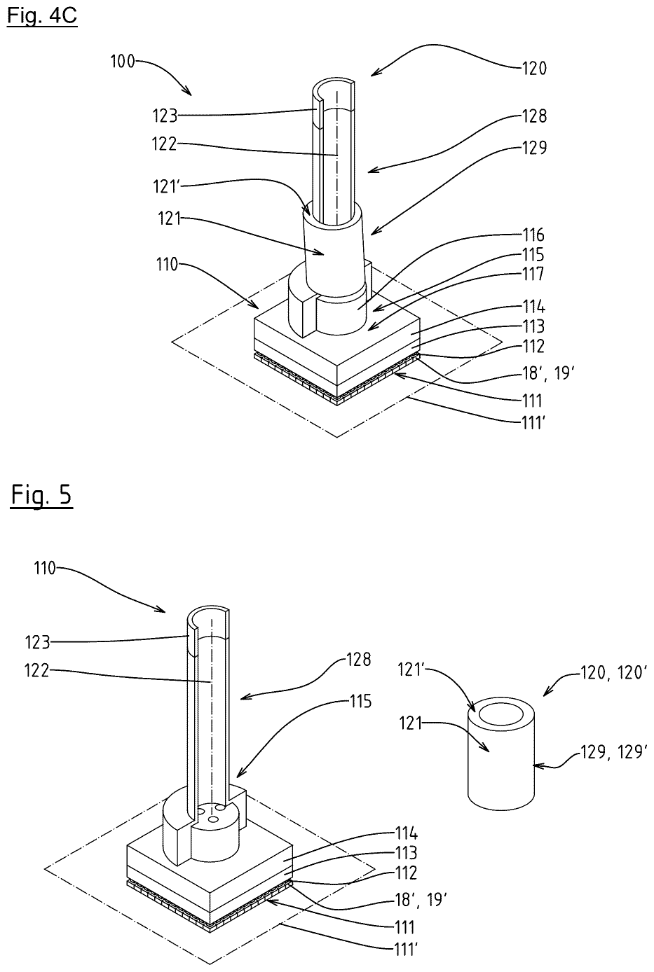

FIG. 5 indicates a third exemplary embodiment of a method according to the disclosure, which largely corresponds to the second exemplary embodiment in accordance with FIGS. 4A-4C, which is why reference is made to the explanations above.

FIG. 5 only shows the initial state for the method according to the disclosure, in a manner comparable to FIGS. 2A and 4A. The main element 129 assigned to the interface element 120 in the exemplary embodiment according to FIG. 4A is now already connected to the spacer element 114 in the initial state and thus part of the MEMS mirror array assembly 110. As a consequence, the main element 129 forms the joining structure 115 of the MEMS mirror array assembly 110, the relative position and pose of which can be measured vis-à-vis the MEMS mirror array structure 111. In an alternative to the separate formation of the main element 129 depicted in FIG. 5, the latter may be formed in one piece with the spacer element 114.

In that case, only the compensating element 129, which merely forms a part of the interface element 120 in FIG. 4A, serves as the interface element 120. In the illustrated exemplary embodiment, the inner diameter of the interface element 120 is adapted to the cylindrical shape of the main element 129 with a clearance fit or transition fit. However, the outer diameter has a significant oversize vis-à-vis the receptacle of the superordinate assembly provided for the MEMS micromirror unit 100, and so suitable machining on the basis of the measurement performed allows the creation of abutment surfaces 121, 121′ which are suitable for compensating for any pose and position errors and as are depicted in FIG. 4C by way of example. FIG. 5 thus depicts a blank 120′ of the interface element 120 or a blank 129′ of the compensating element 129. Unlike the manufacturing process depicted in FIG. 4B, it is only the outer contour and not the inner contour that is modified in the blank 129′, 120′ in order to thus arrive at the desired compensating element 129 or interface element 120.

Subsequently, the interface element 120 can be plugged onto the MEMS mirror array assembly 110 and integrally connected, by soldering for example and in the correct angular position ensurable by suitable markings, to the main element 129 that forms the joining structure 115.

At the end of the production method according to the disclosure, sketched out above, proceeding from the MEMS mirror array assembly 110 and the interface element 120 according to FIG. 5, a MEMS micromirror unit 100, as depicted in FIG. 4C, is obtained.

What is claimed is:

1. A method of producing a MEMS micromirror unit comprising a MEMS mirror array assembly and an interface element configured to secure MEMS micromirror unit to a superordinate assembly, the MEMS mirror array comprising a MEMS mirror array structure and a joining structure on a side facing away from the MEMS mirror array structure, the interface element comprising a joining structure configured to interlock with the joining structure of the MEMS mirror array assembly and an abutment surface configured to position and/or align the MEMS micromirror unit relative to the superordinate assembly, the method comprising:
a) measuring a relative position and pose of the MEMS mirror array structure relative to the joining structure of the MEMS mirror array assembly; and
b) adapting a relative position and/or pose of the joining structure of the interface element and of the abutment surface so that a relative position and/or pose of the MEMS mirror array structure and the abutment surface corresponds to a predetermined position and pose when the MEMS mirror array assembly and the interface element are joined by the joining structure of the MEMS mirror array assembly and the joining structure of the interface element.

2. The method of claim 1, comprising adapting the relative position and/or pose of the joining structure of the interface element and the abutment surface by adapting the joining structure of the interface element.

3. The method of claim 2, comprising adapting the relative position and/or pose of the joining structure f the interface element and of the abutment surface by adapting the abutment surface.

4. The method of claim 3, wherein:
the joining structure of the interface element connects to the MEMS mirror array assembly;
the abutment surface comprises a compensating element secured to joining part of the interface element in a predetermined pose and position; and
the method comprises adapting the relative position and/or pose of the joining structure of the interface element and the abutment surface by processing the compensating element before the abutment surface is secured to the main element.

5. The method of claim 1, comprising adapting the relative position and/or pose of the joining structure f the interface element and of the abutment surface by adapting the abutment surface.

6. The method of claim 5, wherein:
the joining structure of the interface element connects to the MEMS mirror array assembly;
the abutment surface comprises a compensating element secured to joining part of the interface element in a predetermined pose and position; and
the method comprises adapting the relative position and/or pose of the joining structure of the interface element and the abutment surface by processing the compensating element before the abutment surface is secured to the main element.

7. The method of claim 1, comprising adapting the relative position and/or pose of the joining structure of the interface element and the abutment surface in at least two translational degrees of freedom.

8. The method of claim 7, comprising adapting the relative position and/or pose of the joining structure of the interface element and the abutment surface in at least one rotational degree of freedom.

9. The method of claim 1, comprising adapting the relative position and/or pose of the joining structure of the interface element and the abutment surface in at least one rotational degree of freedom.

10. The method of claim 1, wherein the interface element comprises a plurality of abutment surfaces, and the method comprises choosing a number and configuration of the abutment surfaces of the interface element so that, when inserted into the superordinate assembly, at most two degrees of freedom remain.

11. The method of claim 1, wherein the joining structure of MEMS mirror array structure and the joining structure of the interface element are configured to self-center.

12. The method of claim 1, wherein the joining structure of the MEMS mirror array assembly comprises a cylindrically shaped projection.

13. The method of claim 1, comprising force fitting the MEMS mirror array assembly and interface element at the joining structure of the of the MEMS mirror array assembly and the joining structure of the interface element.

14. The method of claim 1, wherein the MEMS mirror array assembly further comprises a substrate comprising an application-specific integrated circuit (ASIC), a rewiring element, and/or a spacer element.

15. The method of claim 14, wherein the joining structure of the MEMS mirror array assembly is one piece with at least one member selected from the group consisting of the ASIC, the rewiring element and the spacer element.

16. The method of claim 1, wherein the interface element has a cylindrical shape or a frustoconical basic shape.

17. A MEMS micromirror unit, comprising:
a MEMS mirror array assembly comprising a MEMS mirror array structure and a joining structure on a side facing away from the MEMS mirror array structure; and
an interface element securing MEMS micromirror unit to a superordinate assembly, the interface element comprising a joining structure interlocking with the joining structure of the MEMS mirror array assembly and an abutment surface configured to position and/or align the MEMS micromirror unit relative to the superordinate assembly so that a relative position and/or pose of the MEMS mirror array structure and the abutment surface corresponds to a predetermined position and pose.

18. An apparatus, comprising:
a MEMS micromirror unit according to claim 17,
wherein the apparatus is a semiconductor technology apparatus.

19. An apparatus, comprising:
a MEMS micromirror unit according to claim 17,
wherein the apparatus is a photolithographic projection exposure apparatus.

20. A method of using a photolithographic projection exposure apparatus comprising an illumination system and a projection system, the method comprising:
using the illumination system to illuminate a reticle in an object field of an object plane of the projection system; and
using the projection system to image the illuminated object into a substrate in an image field in an image plane of the projection system,
wherein the photolithographic projection exposure apparatus comprises a MEMS micromirror unit according to claim 17.
